(19) United States
(12) Patent Application Publication
(10) Pub. No.: US 2021/0359083 A1
(43) Pub. Date: Nov. 18, 2021

(54) SEMICONDUCTOR DEVICE AND METHOD FOR FORMING THE SAME

(71) Applicant: CHANGXIN MEMORY TECHNOLOGIES, INC., Hefei City (CN)

(72) Inventor: Liang ZHAO, Hefei (CN)

(73) Assignee: CHANGXIN MEMORY TECHNOLOGIES, INC., Hefei City (CN)

(21) Appl. No.: 17/388,250

(22) Filed: Jul. 29, 2021

Related U.S. Application Data
(63) Continuation of application No. PCT/CN2021/079979, filed on Mar. 10, 2021.

(30) Foreign Application Priority Data
Mar. 27, 2020 (CN) 202010228551.9

(51) Int. Cl. H01L 49/02

(52) U.S. Cl. CPC H01L 28/60

(57) ABSTRACT

The present application relates to a semiconductor device and a method for forming the same, which can reduce the size of the memory chip and improve the production yield thereof. The semiconductor device includes a substrate; a capacitive post, formed on the surface of the substrate, a length direction of the capacitive post being perpendicular to the surface of the substrate, the capacitive post including: at least three electrode layers which are disposed vertically, forming a side wall of the capacitive post, and a dielectric layer being sandwiched between two adjacent electrode layers; at least two support layers are formed inside the capacitive post, and are in contact with the side wall of the capacitive post for supporting the side wall, and two adjacent support layers being separated by a slot.

### CROSS-REFERENCE TO RELATED APPLICATIONS

This application is a continuation of International Patent Application No. PCT/CN2021/079979, filed on Mar. 10, 2021, which claims priority to Chinese Patent Application No. 202010228551.9, filed on Mar. 27, 2020. The above-referenced applications are incorporated herein by reference in their entirety.

### TECHNICAL FIELD

The present invention relates to the semiconductor manufacturing and processing field, and particularly to a semiconductor device and a method for forming the same.

### BACKGROUND

With developments of science and technology, in the semiconductor manufacturing field, requirements for the size and production yield of semiconductor devices are increasingly high. For example, in the field of memories, an integration density of a memory chip per unit area becomes higher, and it is required that the smaller the size is, the better; however, in prior art, the size of the memory chip is always difficult to be reduced, and in the process of manufacturing memory chips, it is also difficult to improve the production yield thereof.

It is desirable to provide a solution that can reduce the size of the memory chip and increase the yield thereof.

### SUMMARY

The present invention provides an output circuit and a chip to at least resolve the foregoing technical problem in the prior art.

An objective of the invention is to provide a semiconductor device and a method for forming the same, which can reduce the size of a memory chip and improve the production yield thereof.

In order to solve the above technical problem, there is provided a semiconductor device, including: a substrate; a capacitive post extending upwards from an upper surface of the substrate in a direction perpendicular to the upper surface of the substrate, the capacitive post including: at least three vertically disposed electrode layers which form a side wall of the capacitive post, and a dielectric layer being sandwiched between two adjacent electrode layers; at least two support layers are formed inside the capacitive post and are in contact with the side wall of the capacitive post for supporting the side wall, and the two adjacent support layers being separated by a slot.

In order to solve the above technical problem, there is further provided a method for forming a semiconductor device, including the steps of: providing a substrate, the substrate containing at least two sacrificial layers and at least two support layers which are stacked sequentially; forming a hole in the upper surface of the substrate, the hole extending downwards in a direction perpendicular to the surface of the substrate; forming at least three vertically disposed electrode layers on the side wall of the hole, and forming a dielectric layer between two adjacent electrode layers; and removing the sacrificial layers.

In the semiconductor device and the method for forming the same according to the present application, at least three vertically disposed electrode layers are formed on the side wall of capacitive post, one dielectric layer is formed between two adjacent electrode layers, a double-side or multi-side capacitor is formed on the side wall of the capacitive post, such that the finally formed double-side or multi-side capacitor is formed on the side wall of the capacitive post, and an effective area is greater between electrode layers of the double-side or multi-side capacitor, which can realize a great capacitance and lower the requirement of a height of the capacitive post when the great capacitance is required to be realized in the case of a relatively low height of the capacitive post. In addition, in the process of manufacturing such a vertical double-side or multi-side capacitor, a stable double-side or multi-side capacitor structure is formed firstly, and then, the sacrificial layer is removed as needed, so that the capacitive post can be effectively prevented from collapsing in the process of forming the double-side or multi-side capacitor, and the production yield of the semiconductor device is improved.

### BRIEF DESCRIPTION OF DRAWINGS

In order to more clearly illustrate the embodiments of the present application or the technical solutions of the traditional technology, the accompanying drawings required to be used in the description of the embodiments or traditional techniques will be briefly introduced below. Apparently, the accompanying drawings in the following description show merely some embodiments of the present application, and persons of ordinary skill in the art may still derive other drawings from these accompanying drawings without creative efforts.

FIGS. 1a to 1j are schematic structural diagrams of a semiconductor device corresponding to each step when a method for forming a semiconductor device is used according to an embodiment of the present application.

FIG. 1k is a schematic structural diagram of the semiconductor device formed by using the method for forming a semiconductor device according to an embodiment of the present application.

FIG. 2 is a schematic top view of the semiconductor device according to an embodiment of the present application.

FIG. 3 is a schematic flow chart of steps of the method for forming a semiconductor device according to an embodiment of the present application.

### DETAILED DESCRIPTION OF EMBODIMENTS

From research findings, the reason why a size of a memory chip is always difficult to be reduced lies in that it is difficult to ignore a height of a capacitive post in the memory chip. The size of the capacitive post is greatly related to the size of the memory chip. Generally, in order to ensure that a capacitor structure in the capacitive post has a sufficient capacitance, the capacitive post is set to be high enough, which directly results in the fact that the size of the memory is limited by the capacitance provided by the capacitive post and cannot be changed at will.

The reason why a production yield of the memory chip is difficult to improve lies in that one layer of capacitor is formed on each of a side wall and top surface of the capacitive post, and one layer of capacitor is formed on each of an upper surface and a lower surface of the support layer, so that when the capacitive post with such a structure is manufactured, the sacrificial layers on the upper surface and the lower surface of the support layer must be removed before a complete capacitor structure is formed, and the capacitive post is fragile and easy to crack in the manufacture process, which leads to a reduction in the production yield of the memory.

In order to make the objectives, the technical solutions, and the advantages of the embodiments of the present application more clear, the detailed description of the embodiments of the present application is given below in combination with the accompanying drawings. The ordinary skills in the art can understand that many technical details are provided in the embodiments of the present application so as to make the readers better understand the present application. However, even if these technical details are not provided and based on a variety of variations and modifications of the following embodiments, the technical solutions sought for protection in the present application can also be realized. The following embodiments are divided for convenience of description, and should not constitute any limitation to the implementation of the present application. The embodiments may be combined with each other and referred to each other without contradiction.

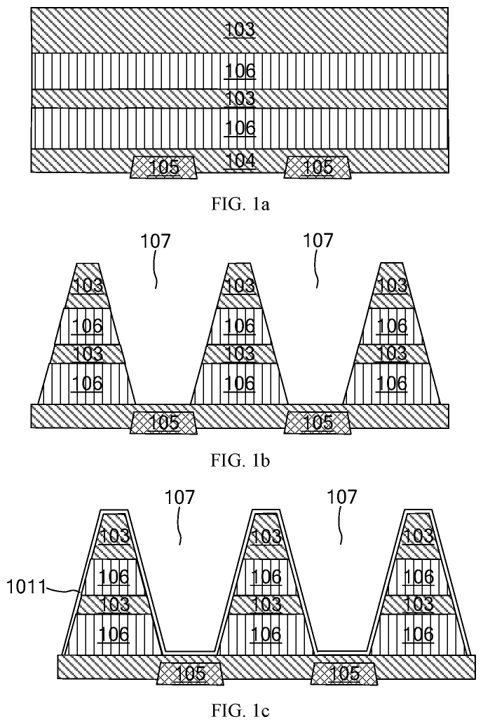

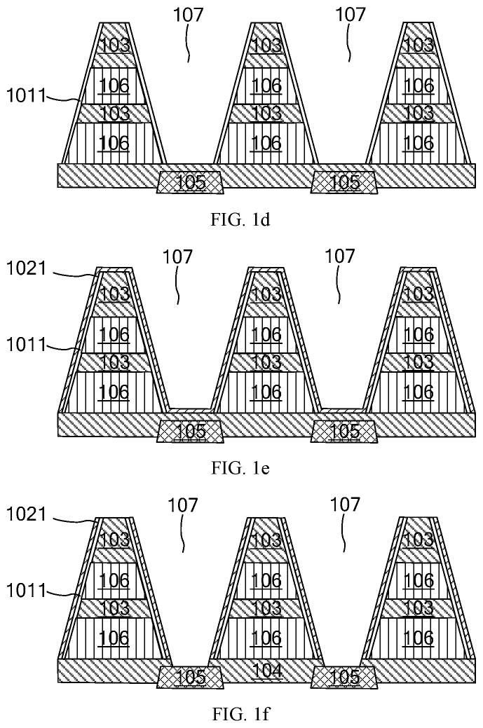

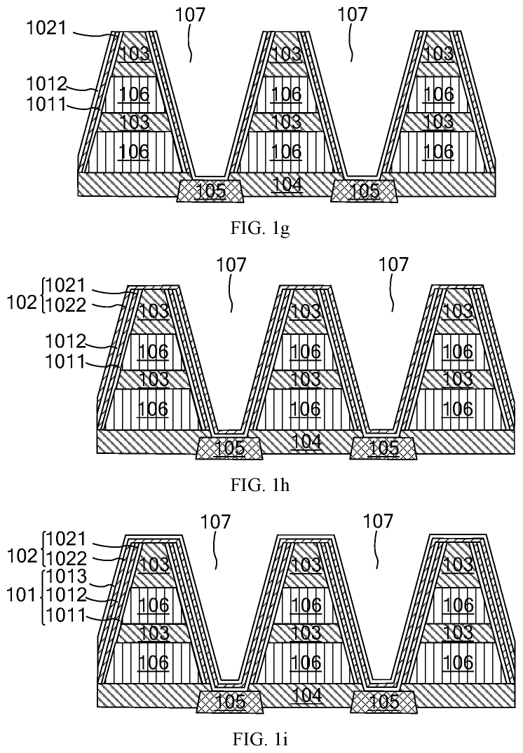

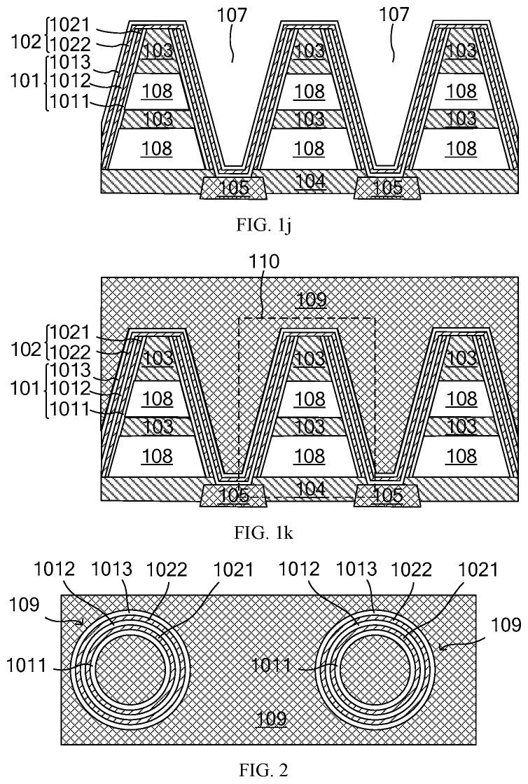

Please refer to FIGS. 1k and 2, in which FIG. 1k is a schematic structural diagram of a semiconductor device formed by the method for forming a semiconductor device according to an embodiment of the present application, and FIG. 2 is a schematic top view of the semiconductor device according to an embodiment of the present application.

In an embodiment shown in FIG. 1k, there is provided a semiconductor device including: a substrate; a capacitive post 110 extending upwards from an upper surface of the substrate in a direction perpendicular to the upper surface of the substrate, the capacitive post 110 including: at least three vertically disposed electrode layers 101 forming a side wall of the capacitive post 110, and a dielectric layer 102 being sandwiched between two adjacent electrode layers 101; at least two support layers 103 formed inside the capacitive post 110, in contact with the side wall of the capacitive post 110, for supporting the side wall, and the two adjacent support layers 103 being separated by a slot 108.

In the present embodiment, the semiconductor device is provided with at least three vertically disposed electrode layers 101, which form the side wall of the capacitive post 110, and a double-side or multi-side capacitor is formed on the side wall of the capacitive post 110, so that the finally formed double-side or multi-side capacitor has a greater effective area. A three-side capacitor structure with four electrode layers 101 and three dielectric layers 102 or a four-side capacitor structure with five electrode layers 101 and four dielectric layers 102 may be formed when a multi-side capacitor is formed on the side wall of the capacitive post 110. Thus, a great capacitance can be realized and the requirement of a height of the capacitive post 110 is lowered when the great capacitance is required to be realized in the case of a relatively low height of the capacitive post 110.

Moreover, with the semiconductor device, after the double-side or multi-side capacitor structure is formed in the manufacturing process, the sacrificial layer 106 is removed as needed, which prevents the capacitive post 110 from collapsing in the process of forming the double-side or multi-side capacitor, thereby improving the production yield of the semiconductor device.

In an embodiment, a section size of the capacitive post 110 is gradually reduced upwards in a direction perpendicular to the upper surface of the substrate, and the section is parallel with the upper surface of the substrate. Since the section size of the capacitive post 110 is gradually reduced upwards in the direction perpendicular to the upper surface of the substrate, a bottom surface of the capacitive post 110 has the greatest interface dimension. Therefore, the capacitive post 110 has a stable structure.

In an embodiment, a dielectric layer 102 formed by a plurality of subdielectric layers may be sandwiched between two adjacent electrode layers 101, and each of the subdielectric layers may be made of a material with a different dielectric constant. For example, the dielectric layer 102 includes a first subdielectric layer and a second subdielectric layer, wherein the first subdielectric layer, which is a zirconium oxide layer, is closer to the support layer 103, and the second subdielectric layer, which is a hafnium oxide layer, covers an outer surface of the first subdielectric layer. In practical use, a composition of the subdielectric layer of the dielectric layer 102, including a specific material composition of the subdielectric layer, and a number of subdielectric layers, may be set as required.

In an embodiment, the capacitive post 110 has a height between 0.1 and 1.8 microns. Actually, the height of the capacitive post 110 may be set as needed. The greater the height of the capacitive post 110, the greater the capacitance.

In one embodiment, a material of the support layer 103 includes at least one of silicon nitride, silicon oxynitride, and aluminum oxide, and a thickness of the support layer 103 may be selected to be between 4 nm and 500 nm.

In one embodiment, the dielectric layer 102 has a dielectric constant of at least 7. In some embodiments, the dielectric layer 102 has a dielectric constant of at least above 7.5. In some embodiments, at least one of zirconium oxide, hafnium oxide, zirconium titanium oxide, ruthenium oxide, antimony oxide, aluminum oxide, or the like may be used as the material of the dielectric layer 102. In fact, the dielectric constant of the dielectric layer 102, or the specific material of the dielectric layer 102, and the thickness of the dielectric layer 102 may be selected as needed.

In one embodiment, the dielectric layer 102 is formed by atomic layer deposition. The atomic layer deposition is the most likely method for manufacturing high-quality dielectric layers 102 with a high dielectric constant, enabling self-limiting growth and precise control over the thickness and chemical composition of the resulting dielectric layer 102, leading to good uniformity and conformality of the resulting dielectric layer 102. In practice, chemical vapor deposition, physical vapor deposition, or the like may also be selected as needed to form the dielectric layer 102.

In one embodiment, the dielectric layer 102 has a thickness of about 3 nm to 500 nm. The thicker the dielectric layer 102, the greater the capacitance of the capacitor structure consisting of the dielectric layer 102 and the electrode layers 101 on both sides of the dielectric layer 102, and therefore, in practice, the thickness of the dielectric layer 102 can be selected as needed, taking requirements of the capacitance and the size of the semiconductor device into account.

In one embodiment, the electrode layer 101 includes at least one of titanium nitride, titanium silicide, nickel silicide, and titanium silicon nitride, a capacitor contact point 105 is disposed in the substrate, the capacitive post 110 is formed above the capacitor contact point 105, and at least one electrode layer 101 is in contact with the capacitor contact point 105.

In one embodiment, at least two capacitive posts 110 are provided, and an upper electrode layer 109 is formed between two adjacent capacitive posts 110, and the upper surface of the capacitive post 110 is covered with the upper electrode layer 109. In one embodiment, the upper electrode includes at least one of tungsten, titanium, nickel, aluminum, platinum, titanium nitride, N-type polysilicon, and P-type polysilicon.

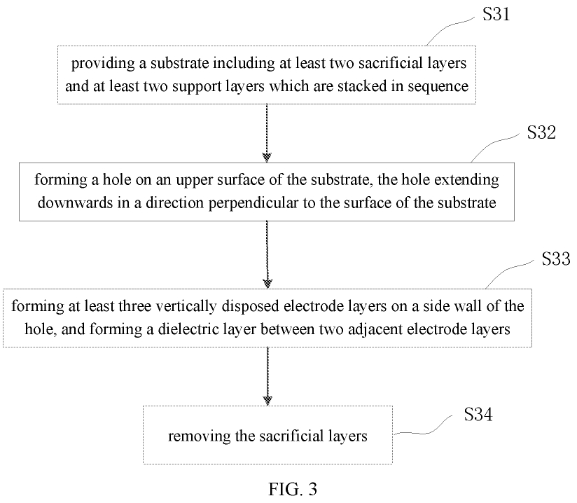

Referring to FIGS. 1a to 1k and FIG. 3, FIGS. 1a to 1j are schematic structural diagrams of a semiconductor device corresponding to steps of a method for forming a semiconductor device according to an embodiment of the present application, and FIG. 3 is a schematic flow chart of steps of the method for forming a semiconductor device according to an embodiment of the present application.

In the present embodiment, there is further provided a method of forming a semiconductor device, including the steps of: S31, providing a substrate including at least two sacrificial layers 106 and at least two support layers 103 which are stacked in sequence, as shown in FIG. 1a; S32, forming a hole 107 on an upper surface of the substrate, the hole 107 extending downwards in a direction perpendicular to the surface of the substrate, as shown in FIG. 1b; S33, forming at least three vertically disposed electrode layers 101 on a side wall of the hole 107, and forming a dielectric layer 102 between two adjacent electrode layers 101, as shown in FIG. 1i; S34, removing the sacrificial layers 106, as shown in FIG. 1j.

According to the present embodiment, in the method for forming a semiconductor device, at least three vertically disposed electrode layers 101 are formed on the side wall of hole 107, one dielectric layer 102 is formed between two adjacent electrode layers, a double-side or multi-side capacitor is formed on the side wall of the capacitive post 110, such that the finally formed double-side or multi-side capacitor is formed on the side wall of the capacitive post 110, and an effective area is greater between electrode layers 101 of the double-side or multi-side capacitor, which can realize a great capacitance and lower the requirement of the height of the capacitive post 110 when the great capacitance is required to be realized in the case of a relatively low height of the capacitive post.

Moreover, in addition, in the process of manufacturing such a vertical double-side or multi-side capacitor, a stable double-side or multi-side capacitor structure is formed firstly, and then, the sacrificial layer 106 is removed as needed, so that the capacitive post 110 can be effectively prevented from collapsing in the process of forming the double-side or multi-side capacitor, and the production yield of the semiconductor device is improved.

In one embodiment, a section size of the hole 107 is gradually reduced from top to bottom in a direction perpendicular to the upper surface of the substrate, and the section is parallel with the upper surface of the substrate.

In one embodiment, the hole 107 is formed in the substrate using photolithography. Specifically, a photomask is first formed on the upper surface of the substrate, then patterned, and a pattern formed by the patterned photomask coincides with a projection of the hole 107 on the upper surface of the substrate. Thus, by directionally etching the substrate downwards through the exposed upper surface of the substrate in a direction perpendicular to the surface of the substrate, the hole 107 is formed in the substrate. The electrode layer 101 and the dielectric layer 102 are formed on the substrate between the two holes 107.

In one embodiment, the substrate surface is formed with a plurality of holes 107, thereby forming a plurality of capacitive posts 110. An aspect ratio of the capacitive post 110 is 4 to 21, preferably 5 to 15, and by setting the aspect ratio of the capacitive post 110, both the capacitance per unit area and an integration level of the semiconductor device can be increased.

In one embodiment, the electrode layer 101 includes a first electrode layer 1011 formed by at least one of chemical vapor deposition, physical vapor deposition and atomic layer deposition on a surface of the side wall of the hole 107, a bottom surface of the hole 107, and the upper surface of the substrate between two adjacent holes 107, as shown in FIG. 1c, and the first electrode layer 1011 located on the bottom surface of the hole 107 and the upper surface of the substrate between two adjacent holes 107 is removed after the first electrode layer 1011 is formed, as shown in FIG. 1d.

In the present embodiment, the first electrode layer 1011 located on the bottom surface of the hole 107 and the upper surface of the substrate between two adjacent holes 107 is removed by dry etching which is directional etching. In practice, the first electrode layer 1011 on the upper surface of the substrate between two adjacent holes 107 can also be removed by chemical mechanical polishing. In fact, the method of removing the first electrode layer 1011 located on the bottom surface of the hole 107 and the upper surface of the substrate between two adjacent holes 107 can be selected as required.

In one embodiment, the dielectric layer 102 includes a first dielectric layer 1021, and the first dielectric layer 1021 is formed on the surface of the side wall of the first electrode layer 1011, the bottom surface of the hole 107, and the upper surface of the substrate between two adjacent holes 107, as shown in FIG. 1e; the first dielectric layer 1021 is a continuous surface, increasing the capacitance; after the formation of the first dielectric layer 1021, the first dielectric layer 1021 located on the bottom surface of the hole 107 and the upper surface of the substrate between two adjacent holes 107 is removed, as shown in FIG. 1f.

In one embodiment, the dielectric layer 102 is formed by at least one of chemical vapor deposition, physical vapor deposition and atomic layer deposition. The first dielectric layer 1021 located on the bottom surface of the hole 107 and the upper surface of the substrate between two adjacent holes 107 is removed by dry etching which is directional etching. In practice, the first dielectric layer 1021 on the upper surface of the substrate between two adjacent holes 107 can also be removed by chemical mechanical polishing. In fact, the method of removing the first dielectric layer 1021 can be selected as required.

In one embodiment, the substrate includes a capacitor contact point 105, the hole 107 is located above the capacitor contact point 105, the substrate further includes a dielectric layer 104 for separating the hole 107 from the capacitor contact point 105, and when the first dielectric layer 1021 located on the bottom surface of the hole 107 and on the upper surface of the substrate between two adjacent holes 107 is removed, the method further includes the following step of removing the dielectric layer 104 between the hole 107 and the capacitor contact point 105 to expose the capacitor contact point 105, as shown in FIG. 1f.

In one embodiment, the electrode layer 101 further includes a second electrode layer 1012 formed on an exposed upper surface of the capacitor contact point 105, the surface of the first dielectric layer 1021, and the upper surface of the substrate between two adjacent holes 107, as shown in FIG. 1g.

In one embodiment, the dielectric layer 102 includes a second dielectric layer 1022 formed on the surface of the second electrode layer 1012 and on the upper surface of the substrate between two adjacent holes 107, as shown in FIG. 1h.

In one embodiment, the electrode layer 101 further includes a third electrode layer 1013 covering the upper surface of the second dielectric layer 1022, as shown in FIG. 1i.

In one embodiment, the electrode layer 101 includes at least one of titanium nitride, titanium silicide, nickel silicide, and titanium silicon nitride, and in fact, the material of the electrode layer 101 and the thickness of each electrode layer 101 can be selected as needed.

In an embodiment, the sacrificial layers 106 are removed by wet etching, and after the removal of the sacrificial layers 106, the electrode layer 109 is filled in the holes 107 until the upper surface of the substrate between two adjacent holes 107 is covered, as shown in FIG. 1k.

In one embodiment, the sacrificial layer 106 and the support layer 103 are made of different materials and have different etching rates in a same etching solution. Specifically, in the same etching solution, the etching rate of the sacrificial layer 106 by the etching solution is much greater than the etching rate of the support layer 103 by the etching solution, so as to ensure that the support layer 103 can be completely reserved or almost completely reserved when the sacrificial layer 106 is completely removed.

In one embodiment, the sacrificial layer 106 includes silicon dioxide, the support layer 103 includes silicon nitride, and the etching solution includes a hydrofluoric acid solution. In one embodiment, the sacrificial layer 106 is doped with boron or phosphorus to guarantee uniformity of critical dimensions and to increase the etching rate of the sacrificial layer 106 when wet etched.

In an embodiment, numbers of the sacrificial layer 106 and the support layer 103 may be set as required. In FIGS. 1a to 1k, two sacrificial layers 106 and two support layers 103 are provided to be stacked on each other in a stacking direction perpendicular to the substrate surface.

In one embodiment, each of the numbers of the sacrificial layer 106 and the support layer 103 is preferably 2 to 6.

In one embodiment, the dielectric layer 102 has a dielectric constant of at least 7, and the electrode layer 101 includes at least one of titanium nitride, titanium silicide, nickel silicide, and titanium silicon nitride.

In some embodiments, the dielectric layer 102 has a dielectric constant of at least above 7.5. In some embodiments, at least one of zirconium oxide, hafnium oxide, zirconium titanium oxide, ruthenium oxide, antimony oxide, aluminum oxide, or the like may be selected as the material of the dielectric layer 102. In fact, the dielectric constant of the dielectric layer 102, or the specific material of the dielectric layer 102, and the thickness of the dielectric layer 102 may be selected as desired.

In one embodiment, the dielectric layer 102 is formed by atomic layer deposition. The atomic layer deposition is the most likely method for manufacturing high-quality dielectric layers 102 with a high dielectric constant, enabling self-limiting growth and precise control over the thickness and chemical composition of the resulting dielectric layer 102, leading to good uniformity and conformality of the resulting dielectric layer 102. In practice, chemical vapor deposition, physical vapor deposition, or the like may also be selected as needed to form the dielectric layer 102.

In one embodiment, the dielectric layer 102 has a thickness of about 3 nm to 500 nm. The thicker the dielectric layer 102, the greater the capacitance of the capacitor structure consisting of the dielectric layer 102 and the electrode layers 101 on both sides of the dielectric layer 102, and therefore, in practice, the thickness of the dielectric layer 102 can be selected as needed, taking requirements of the capacitance and the size of the semiconductor device into account.

The above merely describes preferred embodiments of the present application. It should be pointed that for those skilled in the art, some improvements and polishments, which shall also fall within the protection scope of the present application, may be made without departing the principle of the present application.

What is claimed is:

1. A semiconductor device, comprising:
a substrate;
a capacitive post, extending upwards in a direction perpendicular to an upper surface of the substrate from the upper surface of the substrate, the capacitive post comprising:
at least three electrode layers which are disposed vertically, forming a side wall of the capacitive post, a dielectric layer being sandwiched between two adjacent electrode layers;
at least two support layers are formed inside the capacitive post and are in contact with the side wall of the capacitive post for supporting the side wall, and two adjacent support layers being separated by a slot.

2. The semiconductor device according to claim 1, wherein a section size of the capacitive post is gradually reduced upwards in a direction perpendicular to the upper surface of the substrate, the section being parallel with the upper surface of the substrate.

3. The semiconductor device according to claim 1, wherein the electrode layer comprises at least one of titanium nitride, titanium silicide, nickel silicide and titanium silicon nitride, the substrate is provided therein with a capacitor contact point, the capacitive post is formed above the capacitor contact point, and at least one electrode layer is in contact with the capacitor contact point.

4. The semiconductor device according to claim 1, wherein at least two capacitive posts are provided, an upper electrode layer is formed between two adjacent capacitive posts, and the upper surface of the capacitive post is covered with the upper electrode layer.

5. A method for forming a semiconductor device, comprising:
providing a substrate, the substrate comprising at least two sacrificial layers and at least two support layers which are stacked in sequence;
forming a hole on the upper surface of the substrate, the hole extending downwards in a direction perpendicular to the surface of the substrate;
forming at least three electrode layers which are disposed vertically on the side wall of the hole, and forming a dielectric layer between two adjacent electrode layers; and
removing the sacrificial layers.

6. The method for forming a semiconductor device according to claim 5, wherein the section sizes of the holes are decreased sequentially from top to bottom in a direction perpendicular to the upper surface of the substrate, and the section is parallel with the upper surface of the substrate.

7. The method for forming a semiconductor device according to claim 5, wherein the electrode layer comprises a first electrode layer formed by at least one of chemical vapor deposition, physical vapor deposition and atomic layer deposition on a surface of the side wall of the hole, a bottom surface of the hole and the upper surface of the substrate between two adjacent holes, and the first electrode layer located on the bottom surface of the hole and the upper surface of the substrate between two adjacent holes is removed after the first electrode layer is formed.

8. The method for forming a semiconductor device according to claim 7, wherein the dielectric layer comprises a first dielectric layer formed on a surface of the side wall of the first electrode layer, on the bottom surface of the hole and on the upper surface of the substrate between two adjacent holes, and the first dielectric layer located on the upper surface of the substrate between two adjacent holes is removed after the first dielectric layer is formed.

9. The method for forming a semiconductor device according to claim 8, wherein the substrate comprises a capacitor contact point, the hole is located above the capacitor contact point, the substrate further comprises a dielectric layer for separating the hole from the capacitor contact point, and when the first dielectric layer located on the bottom surface of the hole and on the upper surface of the substrate between two adjacent holes is removed, the method further comprises the following step of:
removing the dielectric layer between the hole and the capacitor contact point to expose the capacitor contact point.

10. The method for forming a semiconductor device according to claim 9, wherein the electrode layer further comprises a second electrode layer formed on an exposed upper surface of the capacitor contact point, on the surface of the first dielectric layer and on the upper surface of the substrate between two adjacent holes.

11. The method for forming a semiconductor device according to claim 10, wherein the dielectric layer comprises a second dielectric layer formed on the surface of the second electrode layer and on the upper surface of the substrate between two adjacent holes.

12. The method for forming a semiconductor device according to claim 11, wherein the electrode layer further comprises a third electrode layer covering the upper surface of the second dielectric layer.

13. The method for forming a semiconductor device according to claim 5, wherein the sacrificial layers are removed by wet etching, and after the removal of the sacrificial layers, the electrode layer is filled in the holes until the upper surface of the substrate between two adjacent holes is covered.

14. The method for forming a semiconductor device according to claim 5, wherein the electrode layer includes at least one of titanium nitride, titanium silicide, nickel silicide and titanium silicon nitride.
